(19) United States
(12) Patent Application Publication
(10) Pub. No.: US 2016/0165754 A1
(43) Pub. Date: Jun. 9, 2016

(54) WATER COOLING HEAT SINK UNIT

(71) Applicant: Vincent Yu, Changhua County (TW)

(72) Inventor: Vincent Yu, Changhua County (TW)

(21) Appl. No.: 14/558,724

(22) Filed: Dec. 3, 2014

(51) Int. Cl. H05K 7/20

(52) U.S. Cl. CPC H05K 7/20254

(57) ABSTRACT

A water cooling heat sink unit includes a base contacting an electronic part with its outside, and the inside of the base has a first groove, a second groove, a main inlet and a main outlet. The first groove communicates with the main outlet and has a first guide portion. The second groove has a second guide portion. A cover is mounted to the inside of the base and has a first corresponding slot, a second corresponding slot, and a corresponding inlet to respectively communicate with the first groove, the second groove and the main inlet. The first corresponding slot has a first corresponding portion which communicates with the first guide portion. The second corresponding slot has a second corresponding portion which communicates with the second guide portion. Cool water is introduced from the first guide portion, the second guide portion, the main inlet and the main outlet.

### BACKGROUND OF THE INVENTION

1. Fields of the Invention

The present invention relates to a heat sink unit, and more particularly, to a water cooling heat sink unit for removing heat from an electronic part.

2. Descriptions of Related Art

The conventional electronic parts such as the processors are requested to operate at high speed and have compact size. The high speed operation for the processor can generate significant amount of heat which has to be removed from the processors so as to keep the processors to operate normally and efficiently. However, the electronic products usually provide narrow space for the electronic parts and the conventional method is cooperated with a fan which cannot quickly bring the heat away. Overheat problems happen and the work has to be stopped, this may cause lost for the users.

A known heat sink unit includes multiple dissipation layers, a base and a cover, wherein the multiple dissipation layers are located on the surface of the electronic part and a groove for water flowing thereby is located above the dissipation layers. The cover is mounted upon the dissipation layers and has holes which are defined through the cover and located corresponding to the groove. An inlet and an outlet are defined through the base so as to introduce cool water. The base has a second groove defined in an underside thereof and the second groove communicates with the inlet and the outlet.

The cool water is introduced into the inlet and flows through the groove via the holes so as to cool the dissipation layers which absorb heat from the electronic part. The water then flows through the second groove and leaves the base from the outlet. The efficiency is not satisfied and a better path for the cool water is needed.

The present invention intends to provide a heat sink unit to eliminate the shortcomings mentioned above.

### SUMMARY OF THE INVENTION

The present invention relates to a water cooling heat sink unit and comprises a heat sink having a base which has its outside facing an electronic part, and the inside of the base has a first groove, a second groove, a main inlet and a main outlet. The first groove communicates with the main outlet. The first groove has at least one guide portion. The second groove has at least one second guide portion which is located at the opposite end of the at least one first guide portion. A cover is mounted to the inside of the base and has a first corresponding slot, a second corresponding slot, and a corresponding inlet. The first corresponding slot communicates with the first groove. The second corresponding groove communicates with the second groove. The corresponding inlet communicates with the main inlet. The first corresponding slot has at least one first corresponding portion which communicates with the at least one first guide portion. The second corresponding slot has at least one second corresponding portion which communicates with the at least one second guide portion. The at least one first guide portion, the at least one second guide portion, the main inlet and the main outlet are connected with a cool water source.

Preferably, the first groove has two first guide portions. The first corresponding slot has two first corresponding portions. The first groove has an upward circulation groove and a downward circulation groove. The upward circulation groove and the downward circulation groove communicate with the main outlet. The two first guide portions are located at two respective distal ends of the upward circulation groove and the downward circulation groove. The two first corresponding portions are located corresponding to the two first guide portions.

Preferably, the second groove has two second guide portions. The second corresponding slot has two second corresponding portions. The second groove has an upward returning groove and a downward returning groove. The second guide portions are connected to two respective distal end of the upward returning groove and the downward returning groove. The two second guide portions communicate with each other. The two second corresponding portions are located corresponding to the two second guide portions. An outward flowing portion is defined at the conjunction portion of the upward returning groove and the downward returning groove. The cover has a drain hole defined in the second corresponding slot and located corresponding to the outward flowing portion.

Preferably, at least one first type heat sink has one side contacting the electronic part, and the other side of the at least one first type heat sink is connected with the heat sink. The at least one first type heat sink has an inlet portion and a drain portion which communicates with the inlet portion. The inlet portion and the drain portion are respectively connected with the first guide portion and the second guide portion of the first groove and the second groove. At least one second type heat sink has one side contacting the electronic part. The at least one first type heat sink and the at least one second type heat sink are located at different portions of the electronic part. The at least one second type heat sink has a sub inlet which communicates with the main inlet. The at least one second type heat sink has a sub outlet which communicates with the main outlet. The sub inlet communicates with the sub outlet.

Preferably, the first guide portion and the second guide portion are holes defined through the base.

Preferably, the first corresponding portion and the second corresponding portion are circular slots.

Preferably, the diameter of the first guide portion and the second guide portion is larger than that of the first groove and the second groove.

The present invention will become more obvious from the following description when taken in connection with the accompanying drawings which show, for purposes of illustration only, a preferred embodiment in accordance with the present invention.

### BRIEF DESCRIPTION OF THE DRAWINGS

FIG. 1 is a perspective view to show the heat sink unit of the present invention is coupled to the electronic part;

FIG. 2 is an exploded view to show the cover and the base of the heat sink unit of the present invention;

FIG. 3 is an enlarged exploded view to show the cover and the base of the heat sink unit of the present invention;

FIG. 4 is another exploded view to show the cover and the base of the heat sink unit of the present invention;

FIG. 5 shows the flow direction of the cool water;

FIG. 6 shows the base, the first type heat sink and the second type heat sink of the present invention, and

FIG. 7 is a cross sectional view, taken along line A-A in FIG. 1.

### DETAILED DESCRIPTION OF THE PREFERRED EMBODIMENT

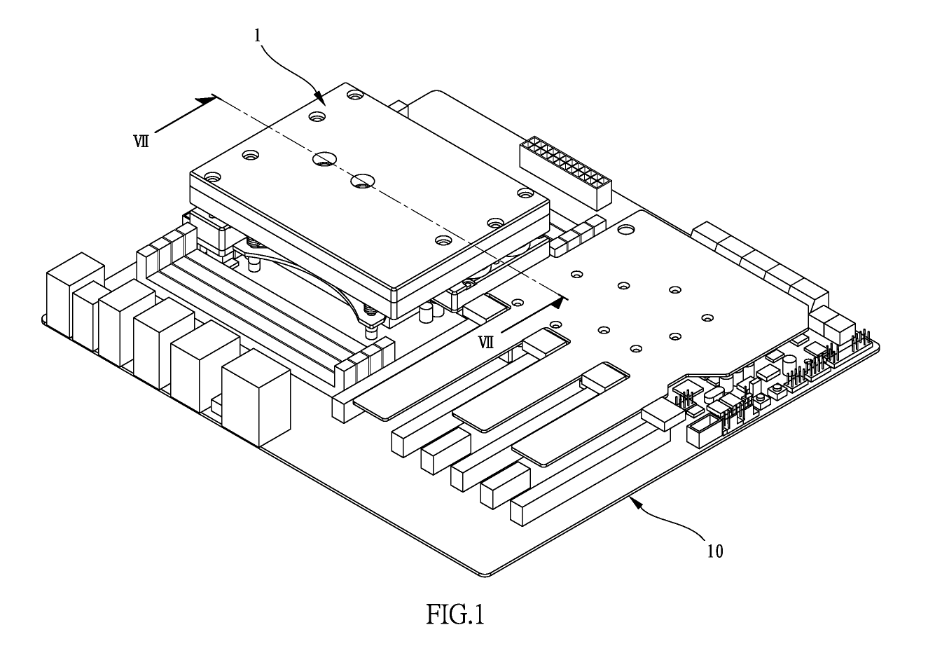

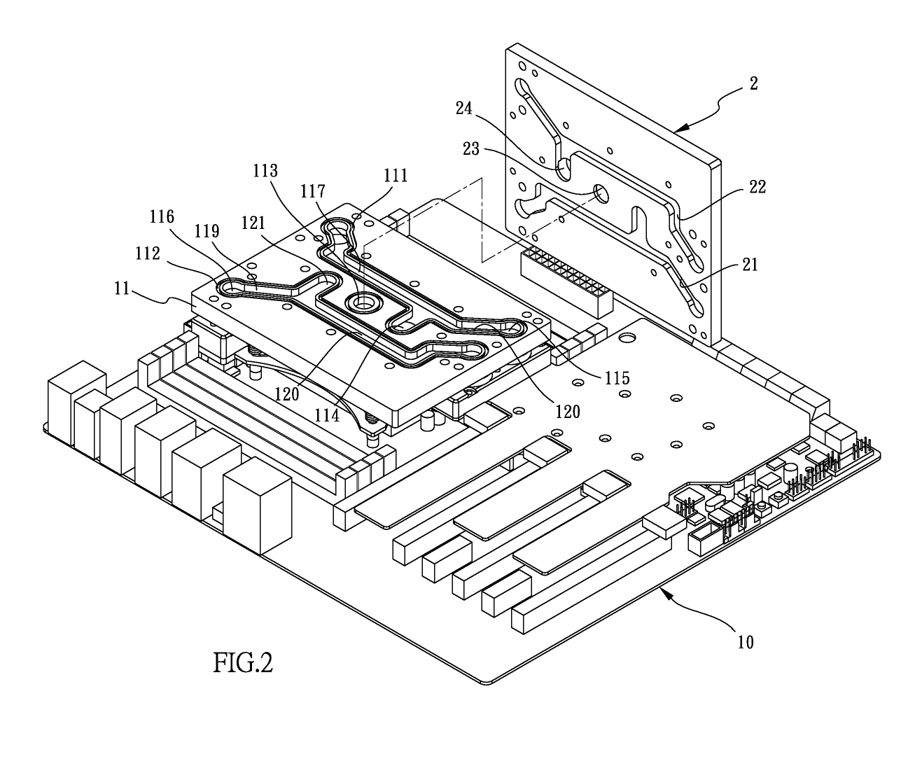

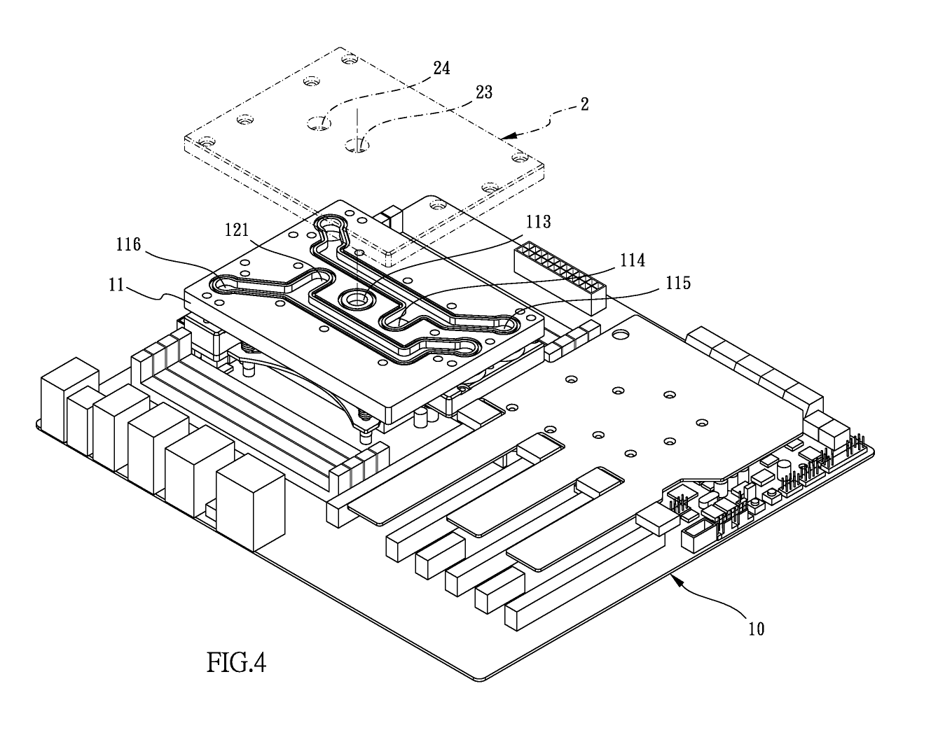

Referring to FIGS. 1 to 4, the heat sink unit of the present invention comprises a heat sink 1 which has a base 11 and a cover 2, wherein the base 11 has its outside facing/contacting an electronic part 10, and the inside of the base 11 has a first groove 111, a second groove 112, a main inlet 113 and a main outlet 114. The first groove 111 communicates with the main outlet 114. The first groove 111 has at least one guide portion 115. The second groove 112 has at least one second guide portion 116 which is located at the opposite end of the at least one first guide portion 115.

The cover 2 is mounted to the inside of the base 11 and has a first corresponding slot 21, a second corresponding slot 22, and a corresponding inlet 23. The first corresponding slot 21 communicates with the first groove 111. The second corresponding groove 22 communicates with the second groove 112. The corresponding inlet 23 communicates with the main inlet 113. The first corresponding slot 21 has at least one first corresponding portion 211 which communicates with the at least one first guide portion 115. The second corresponding slot 22 has at least one second corresponding portion 221 which communicates with the at least one second guide portion 116. The at least one first guide portion 115, the at least one second guide portion 116, the main inlet 113 and the main outlet 114 can be connected with a cool water source 20. The cool water or cooling agent (cool water hereinafter) is introduced from the main inlet 113, and the flows through the path composed of the first groove 111 and the first corresponding slot 21. The cool water flows out from the first groove 111 and the first corresponding slot 21 via the first guide portion 115 and the first corresponding portion 211. The first guide portion 115 introduces the cool water to the second groove 112. The second groove 112 and the second corresponding slot 22 from a path to guide the cool water. By this way, a path for the cool water is established.

Besides, the base 11 and the cover 2 are two individual parts which are easily cleaned.

The first groove 111 has two first guide portions 115. The first corresponding slot 21 has two first corresponding portions 211. The first groove 11 has an upward circulation groove 117 and a downward circulation groove 118, wherein the upward circulation groove 117 and the downward circulation groove 118 communicate with the main outlet 114. The two first guide portions 115 are located at two respective distal ends of the upward circulation groove 117 and the downward circulation groove 118. The two first corresponding portions 211 are located corresponding to the two first guide portions 115. When the main outlet 114 introduces the cool water to the first and second grooves 111, 112, the cool water flows through the upward circulation groove 117 and the downward circulation groove 118, and to the two first guide portions 115 so as to accelerate the movement of the cool water. The first corresponding portion 211 is used to receive more cool water. The first corresponding slot 21 and the first groove 111 are located corresponding to each other, so that the detail structure of the first corresponding slot 21 will not be described.

The second groove 112 has two second guide portions 116, the second corresponding slot 22 has two second corresponding portions 221. The second groove 12 has an upward returning groove 119 and a downward returning groove 120. The second guide portions 116 are connected to two respective distal end of the upward returning groove 119 and the downward returning groove 120. The two second guide portions 116 communicate with each other. The two second corresponding portions 221 are located corresponding to the two second guide portions 116. An outward flowing portion 121 is defined at the conjunction portion of the upward returning groove 119 and the downward returning groove 120. The cover 2 has a drain hole 24 defined in the second corresponding slot 22 and located corresponding to the outward flowing portion 121. The first guide portion 115 introduces cool water, and the upward returning groove 119 and the downward returning groove 120 accelerate the speed of the cool water, and quickly collect the cool water at the outside of the heat sink unit and then drain the cool water from the drain hole 24.

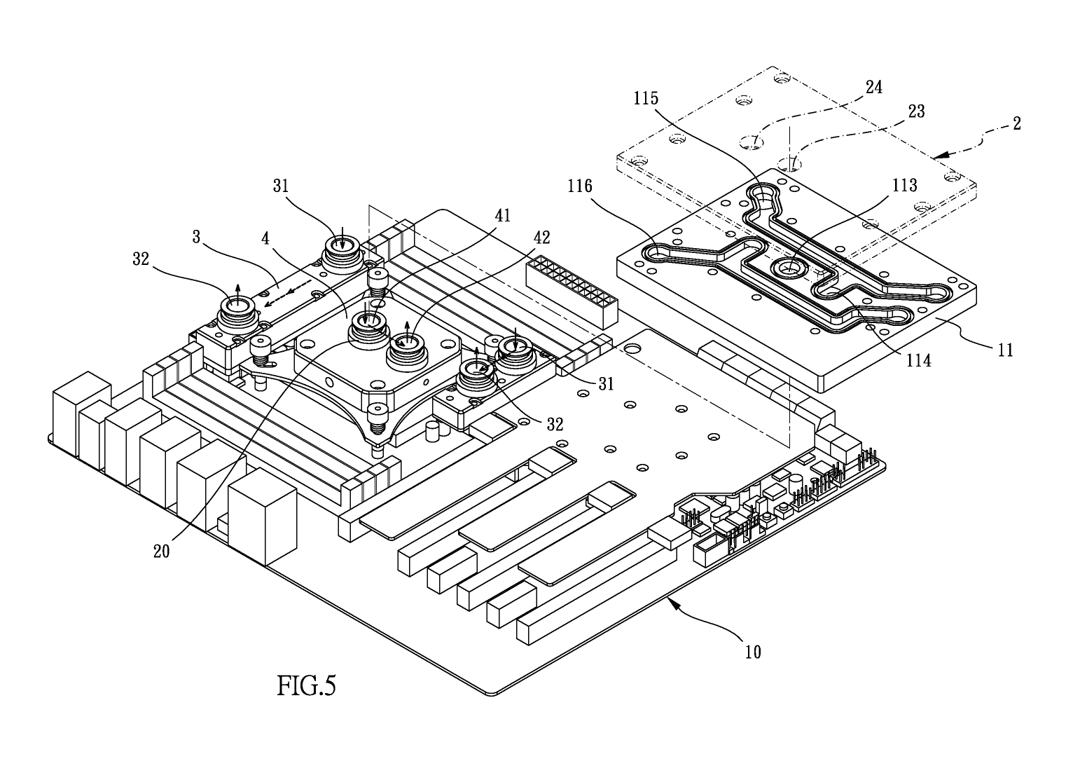

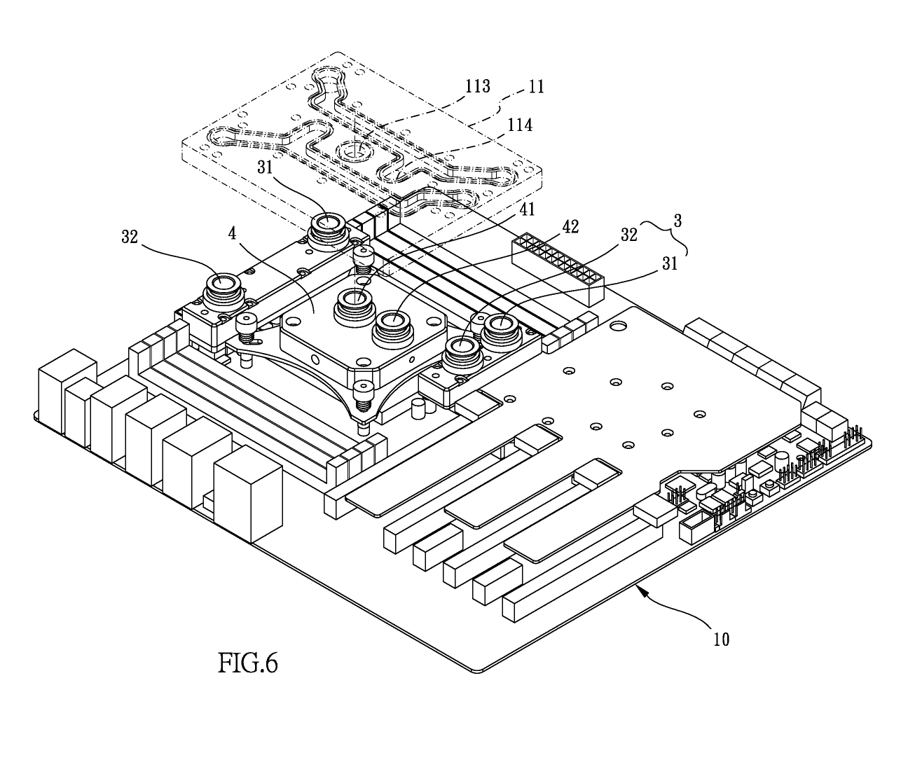

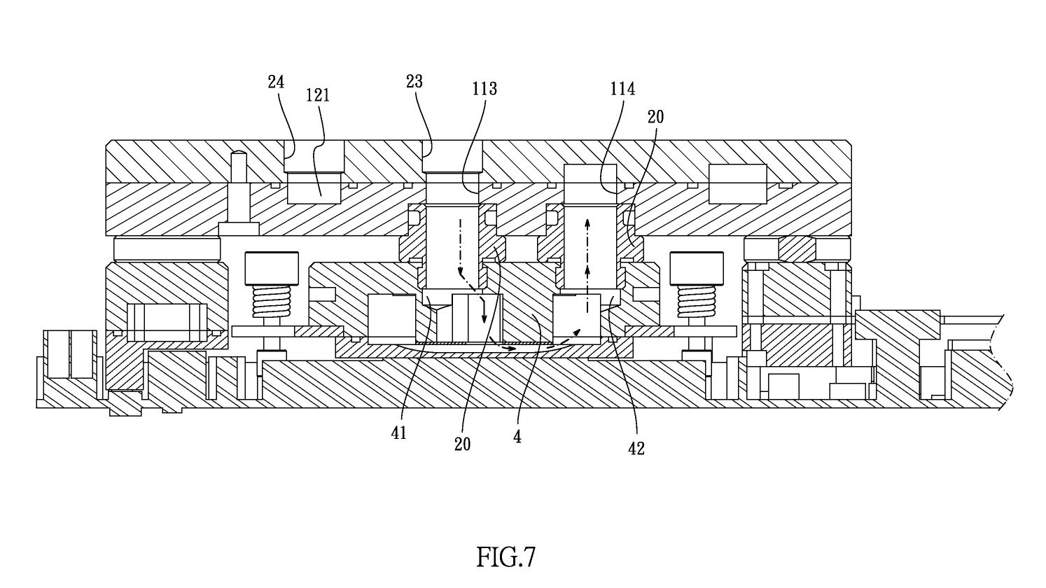

As shown in FIGS. 5 to 7, the heat sink unit of the present invention further comprises at least one first type heat sink 3 and at least one second type heat sink 4. The at least one first type heat sink 3 has one side contacting the electronic part 10, and the other side of the at least one first type heat sink 3 is connected with the heat sink 1. The at least one first type heat sink 3 has an inlet portion 31 and a drain portion 32 which communicates with the inlet portion 31. The inlet portion 31 and the drain portion 32 are respectively connected with the first guide portion 115 and the second guide portion 116 of the first groove 111 and the second groove 112. The at least one second type heat sink 4 has one side contacting the electronic part 10. The at least one first type heat sink 3 and the at least one second type heat sink 4 are located at different portions of the electronic part 10. The at least one second type heat sink 4 has a sub inlet 41 which communicates with the main inlet 113. The at least one second type heat sink 4 has a sub outlet 42 which communicates with the main outlet 114, the sub inlet 41 communicating with the sub outlet 42. The inlet portion 31 of the first type heat sink 3 introduces the cool water that flows out from the heat sink 1, and the drain portion 32 drains the cool water to the heat sink 3. The sub inlet 41 of the second type heat sink 4 introduces the cool water that flows out from the heat sink 1, and the sub outlet 42 drains the cool water to the heat sink 3. By the circulation of the cool water in the first type heat sink 3 and the second type heat sink 4, the heat from the electronic part 10 can be quickly brought away.

The first guide portion 115 and the second guide portion 116 are holes defined through the base 11 so as to be connected with the cool water source 20.

Besides, the first corresponding portion 211 and the second corresponding portion 221 are circular slots so as to increase the volume that flows through.

The diameter of the first guide portion 115 and the second guide portion 116 is larger than that of the first groove 111 and the second groove 112. Therefore, the volume of the cool water can be increased and the cool water is collected at the first and second corresponding portions 211, 221.

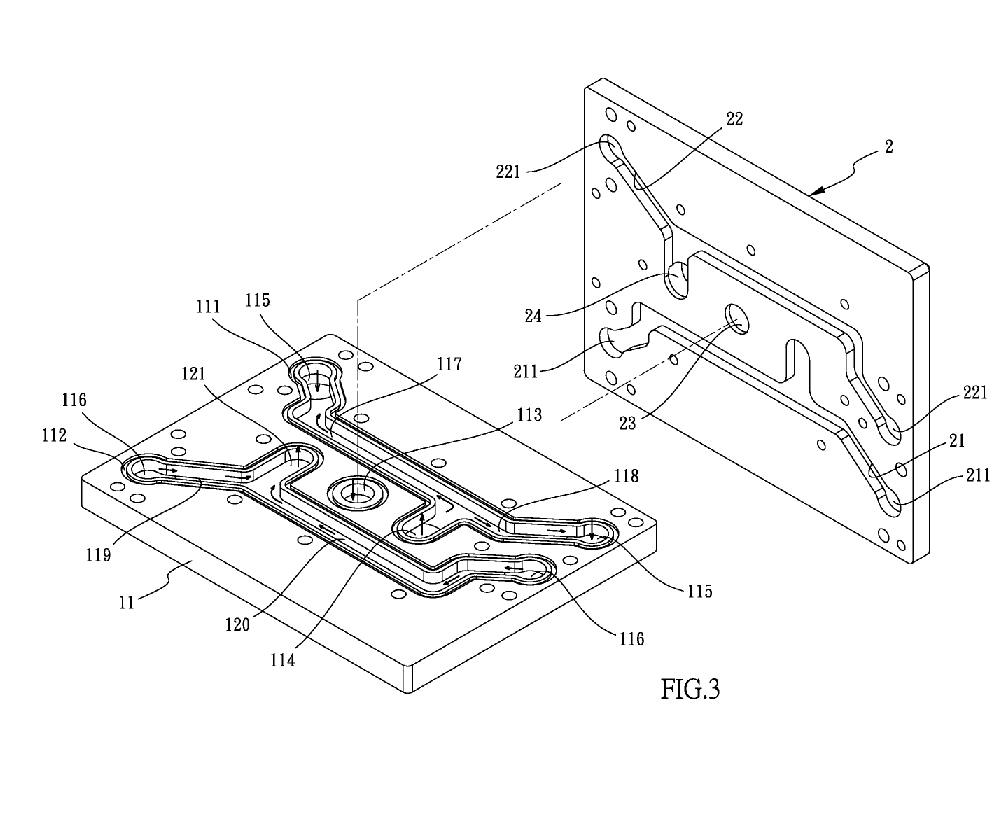

As shown in FIGS. 3 to 5, the cool water is introduced from the corresponding inlet 23 and flows through the main inlet 113, the base 11, the main outlet 114, the upward circulation groove 117 and the downward circulation groove 118 of the first groove 111, the first corresponding slot 21, the first guide portion 115 and the first corresponding portion 211, and then eventually drained to the two first type heat sinks 3. The cool water is introduced from the inlet portion 31 of the first type heat sink 3 and drained from the drain portion 32. The cool water then enters into the second groove 112 via the second guide portion 116. The cool water is collected at the outward flowing portion 121 via the upward returning groove 119 and the downward returning groove 120, and then drained out from the drain hole 24 to form a circulation path to cool the electronic part 10.

While we have shown and described the embodiment in accordance with the present invention, it should be clear to those skilled in the art that further embodiments may be made without departing from the scope of the present invention.

What is claimed is:

1. A water cooling heat sink unit comprising:
a heat sink (1) having a base (11) having an outside facing an electronic part (10), an inside of the base (11) having a first groove (111), a second groove (112), a main inlet (113) and a main outlet (114), the first groove (111) communicating with the main outlet (114), the first groove (111) having at least one guide portion (115), the second groove (112) having at least one second guide portion (116) which is located at an opposite end of the at least one first guide portion (115);
a cover (2) mounted to the inside of the base (11) and having a first corresponding slot (21), a second corresponding slot (22), and a corresponding inlet (23), the first corresponding slot (21) communicating with the first groove (111), the second corresponding groove (22) communicating with the second groove (112), the corresponding inlet (23) communicating with the main inlet (113), the first corresponding slot (21) having at least one first corresponding portion (211) which communicates with the at least one first guide portion (115), the second corresponding slot (22) having at least one second corresponding portion (221) which communicates with the at least one second guide portion (116), and
the at least one first guide portion (115), the at least one second guide portion (116), the main inlet (113) and the main outlet (114) connected with a cool water source (20).

2. The heat sink unit as claimed in claim 1, wherein the first groove (111) has two first guide portions (115), the first corresponding slot (21) has two first corresponding portions (211), the first groove (11) has an upward circulation groove (117) and a downward circulation groove (118), the upward circulation groove (117) and the downward circulation groove (118) communicate with the main outlet (114), the two first guide portions (115) are located at two respective distal ends of the upward circulation groove (117) and the downward circulation groove (118), the two first corresponding portions (211) are located corresponding to the two first guide portions (115).

3. The heat sink unit as claimed in claim 1, wherein the second groove (112) has two second guide portions (116), the second corresponding slot (22) has two second corresponding portions (221), the second groove (12) has an upward returning groove (119) and a downward returning groove (120), the second guide portions (116) are connected to two respective distal end of the upward returning groove (119) and the downward returning groove (120), the two second guide portions (116) communicate with each other, the two second corresponding portions (221) are located corresponding to the two second guide portions (116), an outward flowing portion (121) is defined at a conjunction portion of the upward returning groove (119) and the downward returning groove (120), the cover (2) has a drain hole (24) defined in the second corresponding slot (22) and located corresponding to the outward flowing portion (121).

4. The heat sink unit as claimed in claim 1 further comprising at least one first type heat sink (3) and at least one second type heat sink (4), the at least one first type heat sink (3) having one side contacting the electronic part (10), the other side of the at least one first type heat sink (3) being connected with the heat sink (1), the at least one first type heat sink (3) having an inlet portion (31) and a drain portion (32) which communicates with the inlet portion (31), the inlet portion (31) and the drain portion (32) respectively connected with the first guide portion (115) and the second guide portion (116) of the first groove (111) and the second groove (112), the at least one second type heat sink (4) having one side contacting the electronic part (10), the at least one first type heat sink (3) and the at least one second type heat sink (4) located at different portions of the electronic part (10), the at least one second type heat sink (4) having a sub inlet (41) which communicates with the main inlet (113), the at least one second type heat sink (4) having a sub outlet (42) which communicates with the main outlet (114), the sub inlet (41) communicating with the sub outlet (42).

5. The heat sink unit as claimed in claim 1, wherein the first guide portion (115) and the second guide portion (116) are holes defined through the base (11).

6. The heat sink unit as claimed in claim 1, wherein the first corresponding portion (211) and the second corresponding portion (221) are circular slots.

7. The heat sink unit as claimed in claim 1, wherein a diameter of the first guide portion (115) and the second guide portion (116) is larger than that of the first groove (111) and the second groove (112).
